(19) United States
(12) Patent Application Publication
(10) Pub. No.: US 2025/0024596 A1
(43) Pub. Date: Jan. 16, 2025

(54) SUBSTRATE FOR PRINTED WIRING BOARD

(71) Applicants: SUMITOMO ELECTRIC INDUSTRIES, LTD., Osaka (JP); SUMITOMO ELECTRIC PRINTED CIRCUITS, INC., Shiga (JP)

(72) Inventors: Ryo IRIGUCHI, Osaka (JP); Issei OKADA, Osaka (JP)

(73) Assignees: SUMITOMO ELECTRIC INDUSTRIES, LTD., Osaka (JP); SUMITOMO ELECTRIC PRINTED CIRCUITS, INC., Shiga (JP)

(21) Appl. No.: 18/712,757

(22) PCT Filed: Nov. 11, 2022
(86) PCT No.: PCT/JP2022/042083

§ 371 Date: May 23, 2024

(30) Foreign Application Priority Data
Nov. 30, 2021 (JP) 2021-194846

(51) Int. Cl. H05K 1/03; H05K 1/02

(52) U.S. Cl. CPC H05K 1/0373; H05K 1/0266; H05K 2201/0129; H05K 2201/0154

(57) ABSTRACT

A substrate for a printed wiring board according to the present disclosure includes: a base material layer containing a thermoplastic resin; a metal nanoparticle layer, and a plating layer. The base material layer, the metal nanoparticle layer, and the plating layer are stacked in this order, and some of metal nanoparticles in the metal nanoparticle layer are embedded in the base material layer.

### TECHNICAL FIELD

The present disclosure relates to a substrate for a printed wiring board. The present application claims priority based on Japanese Patent Application No. 2021-194846 filed on Nov. 30, 2021. The entire contents of the Japanese patent application are incorporated herein by reference.

### BACKGROUND ART

There has been used a base member for a printed wiring board, the base member including: an insulating substrate made of a resin or the like; a metal nanoparticle layer stacked on a surface of the substrate; and a plating layer stacked on a surface of the metal nanoparticle layer on the side opposite to the substrate. A plating layer is formed on the metal nanoparticle layer of the base member for a printed wiring board. Then, the metal nanoparticle layer and the plating layer are patterned in a plan view to form a conductive pattern, to thereby form a substrate for a printed wiring board.

This type of base member for a printed wiring board needs to be excellent in adhesiveness between the substrate and the metal nanoparticle layer so as to prevent the conductive pattern from being peeled off from the substrate when bending stress is applied to the substrate for a printed wiring board.

In recent years, densification of a substrate for a printed wiring board is demanded as electronic devices have been reduced in size and increased in performance. Due to densification of a substrate for a printed wiring board, the conductive pattern becomes finer and thus is easily peeled off from the substrate. Accordingly, also from this viewpoint, the base member for a printed wiring board needs to be excellent in adhesiveness between a base film and a metal layer. As the base member for a printed wiring board, there has been proposed a base member formed by attaching a metal foil to a resin film by hot pressing (thermocompression bonding) or the like (Japanese Patent Laying-Open No. 2017-199802).

### CITATION LIST

### Patent Literature

PTL 1: Japanese Patent Laying-Open No. 2017-199802

### SUMMARY OF INVENTION

A substrate for a printed wiring board according to the present disclosure includes a base material layer containing a thermoplastic resin, a metal nanoparticle layer, and a plating layer. The base material layer, the metal nanoparticle layer, and the plating layer are stacked in this order. Some of metal nanoparticles in the metal nanoparticle layer are embedded in the base material layer.

### BRIEF DESCRIPTION OF DRAWINGS

FIG. 1 is a schematic cross-sectional view showing a substrate for a printed wiring board according to an embodiment.

FIG. 2 is a photograph (at a magnification of 100000×) taken with an electron microscope and showing a cross section of a substrate for a printed wiring board of Example 1.

FIG. 3 is a photograph (at a magnification of 100000×) taken with an electron microscope and showing a cross section of a substrate for a printed wiring board of Comparative Example 2.

FIG. 4 is a photograph (at a magnification of 100000×) taken with an electron microscope and showing a surface of a base material layer exposed after a peeling test conducted on the substrate for a printed wiring board of Example 1.

FIG. 5 is a photograph (at a magnification of 100000×) taken with an electron microscope and showing a surface of a base material layer exposed after a peeling test conducted on the substrate for a printed wiring board of Comparative Example 2.

FIG. 6 is a binary image of a region from which a metal nanoparticle layer has been peeled off in Example 1.

FIG. 7 is a diagram showing results obtained by an electron energy loss spectroscopy (EELS) analysis through an observation of the cross section of the substrate for a printed wiring board of Example 1 with a transmission electron microscope.

FIG. 8 is a graph showing results obtained by the EELS analysis through an observation of the cross section of the substrate for a printed wiring board of Example 1 with a transmission electron microscope.

FIG. 9 is a diagram showing results obtained through an observation of the surface of the base material layer etched with copper chloride at a magnification of 100000×with an electron microscope.

FIG. 10 is a schematic cross-sectional view for illustrating recesses as marks of embedment and a maximum width among widths of the recesses at the surface of the base material layer.

### DETAILED DESCRIPTION

### [Problem to be Solved by the Present Disclosure]

In the substrate for a printed wiring board as proposed above, irregularities of about several μm may be formed on a metal foil during thermocompression bonding of this metal foil, which may make it difficult to form fine conductive patterns on the substrate for a printed wiring board.

Thus, an object herein is to provide a substrate for a printed wiring board, the substrate being excellent in adhesiveness and allowing a fine conductive pattern to be formed thereon.

### [Advantageous Effect of the Present Disclosure]

According to the present disclosure, there is provided a substrate for a printed wiring board, the substrate being excellent in adhesiveness and allowing a fine conductive pattern to be formed thereon.

### [Description of Embodiments of the Present Disclosure]

A substrate for a printed wiring board according to the present disclosure includes: a base material layer containing a thermoplastic resin; a metal nanoparticle layer; and a plating layer. The base material layer, the metal nanoparticle layer, and the plating layer are stacked in this order. A surface portion of the metal nanoparticle layer on the side close to the base material layer is embedded in the base material layer.

In other words, a substrate for a printed wiring board of the present disclosure includes: a base material layer containing a thermoplastic resin; a metal nanoparticle layer; and a plating layer. The base material layer, the metal nanoparticle layer, and the plating layer are stacked in this order. Some of metal nanoparticles in the metal nanoparticle layer are embedded in the base material layer.

In the substrate for a printed wiring board of the present disclosure, some of metal nanoparticles in the metal nanoparticle layer are embedded in the surface of the base material layer containing a thermoplastic resin as a main component, which brings about an anchor effect between the base material layer and the metal nanoparticle layer, thus resulting in an excellent adhesiveness between the base material layer and the metal nanoparticle layer. On the other hand, the plating layer stacked on the metal nanoparticle layer has a smooth outer surface, and therefore, a fine conductive pattern can be formed on the substrate for a printed wiring board. In this case, the “nanoparticle” means a particle whose average particle diameter is less than 1 μm. This average particle diameter is calculated as one-half of the sum of: the maximum length obtained through a microscopic observation; and the maximum width in the direction perpendicular to the direction of this length. The “main component” is a component contained in highest content and means a component contained, for example, by 50% by mass or more in the base material layer. The boundary between the metal nanoparticle layer and the base material layer has an irregularity structure. Further, the configuration in which some of metal nanoparticles in the metal nanoparticle layer are embedded in the base material layer means a configuration in which the metal nanoparticles are received in respective recesses in the base material layer in a region having a thickness of several tens of nm to several hundreds of nm from the outermost surface (a protruding portion of the metal nanoparticle layer) of the metal nanoparticle layer on the base material layer side. The surface portion of the metal nanoparticle layer on the base material layer side means a region having a thickness of several tens of nm to several hundreds of nm from the outermost surface (a protruding portion of the metal nanoparticle layer) of the metal nanoparticle layer on the base material layer side. Further, from a different point of view, the substrate for a printed wiring board has an irregularity structure at the boundary between the metal nanoparticle layer and the base material layer. The irregularity structure is formed by the metal nanoparticles forming the metal nanoparticle layer and the base material layer. It can also be said that the metal nanoparticles forming the metal nanoparticle layer and the components forming the base material layer are intermixed at the boundary between the metal nanoparticle layer and the base material layer.

The 180-degree peel strength with which the metal nanoparticle layer is peeled off from the base material layer may be 5 N/cm or more. In this way, the metal nanoparticle layer having a 180-degree peel strength of 5 N/cm or more tends to make it difficult to peel off the conductive pattern formed on the substrate for a printed wiring board from the substrate. The “180-degree peel strength with which the metal nanoparticle layer is peeled off from the base material layer” means the 180-degree peel strength with which the metal nanoparticle layer is peeled off together with the plating layer from the base material layer. The “180-degree peel strength” means a peel (peeling) force measured when the metal nanoparticle layer is peeled off together with the plating layer from the base material layer, according to JIS-K6854-2:1999 “Adhesives—Determination of peel strength of bonded assemblies—Part 2:180 degree peel”.

The average particle diameter of the metal nanoparticles in the metal nanoparticle layer is preferably 1 nm or more and 500 nm or less. When the average particle diameter of the metal nanoparticles in the metal nanoparticle layer is within the above-mentioned range, the dispersibility and the dispersion stability of the metal nanoparticles in the metal nano-ink are improved, thus allowing for a uniform thickness of a metal nanoparticle layer 3, and also allowing for an excellent surface property of the metal nanoparticle layer. From a different point of view, the irregularity structure at the boundary between the metal nanoparticle layer and the base material layer is formed by the metal nanoparticles forming the metal nanoparticle layer and the base material layer. Thus, it can also be said that the irregularity structure is also influenced by the average particle diameter of the metal nanoparticles. In other words, the irregularity structure in which the average particle diameter of the metal nanoparticles is 1 nm or more and 500 nm or less may be preferable. The “average particle diameter” means a particle diameter at which the volume integrated value attains 50% in a distribution of particle diameters measured by laser diffractometry.

It is preferable that the surface of the base material layer has marks of embedment including a plurality of recesses after the metal nanoparticle layer is peeled off. When the surface of the base material layer has marks of embedment including a plurality of recesses after the metal nanoparticle layer is peeled off, some of the metal nanoparticles in the metal nanoparticle layer are sufficiently embedded in the surface of the base material layer, so that the adhesiveness between the base material layer and the metal nanoparticle layer can be improved. In this case, the recesses each are a portion recessed from an average position on the surface.

In a plan view of a region of the surface of the base material layer from which the metal nanoparticle layer has been peeled off, an area ratio of the recesses is preferably 5% or more. When the area ratio of the recesses is 5% or more in a plan view of the region of the surface of the base material layer from which the metal nanoparticle layer has been peeled off, some of the metal nanoparticles in the metal nanoparticle layer are sufficiently embedded in the surface of the base material layer, so that the adhesiveness between the base material layer and the metal nanoparticle layer can be improved. The area ratio can be calculated from an image obtained by an observation with a scanning electron microscope.

At the surface of the base material layer from which the metal nanoparticle layer has been peeled off, a maximum width among widths of the recesses is preferably 1 nm or more in a plan view. When the maximum width among the widths of the recesses at the surface of the base material layer from which the metal nanoparticle layer has been peeled off is 1 nm or more in a plan view, some of the metal nanoparticles in the metal nanoparticle layer are sufficiently embedded in the surface of the base material layer, so that the adhesiveness between the base material layer and the metal nanoparticle layer can be improved.

The thermoplastic resin may be polyimide. When the thermoplastic resin is polyimide in this way, the heat resistance of the substrate for a printed wiring board is further improved.

It is preferable that the base material layer includes a first resin layer containing a thermoplastic resin as a main component and a second resin layer containing a thermosetting resin as a main component, and the second resin layer, the first resin layer, and the metal nanoparticle layer are stacked in this order. When the base material layer further includes the second resin layer containing the thermosetting resin as a main component, the dimensional stability of the base material layer can be improved.

It is preferable that the base material layer includes: a first resin layer containing a first thermoplastic resin as a main component; a second resin layer containing a thermosetting resin as a main component; and a third resin layer containing a second thermoplastic resin as a main component, the third resin layer, the second resin layer, and the first resin layer are stacked in this order, and the metal nanoparticle layer is stacked at least on a surface of the first resin layer or the third resin layer. The first thermoplastic resin and the second thermoplastic resin may be the same material or different materials. When the base material layer includes the first resin layer containing a thermoplastic resin as a main component, the second resin layer containing a thermosetting resin as a main component, and the third resin layer containing a thermoplastic resin as a main component, the dimensional stability of the base material layer can be further improved.

### [Details of Embodiments of the Present Disclosure]

Hereinafter, embodiments of a substrate for a printed wiring board according to the present disclosure will be described in detail with reference to the accompanying drawings.

### [Substrate for Printed Wiring Board]

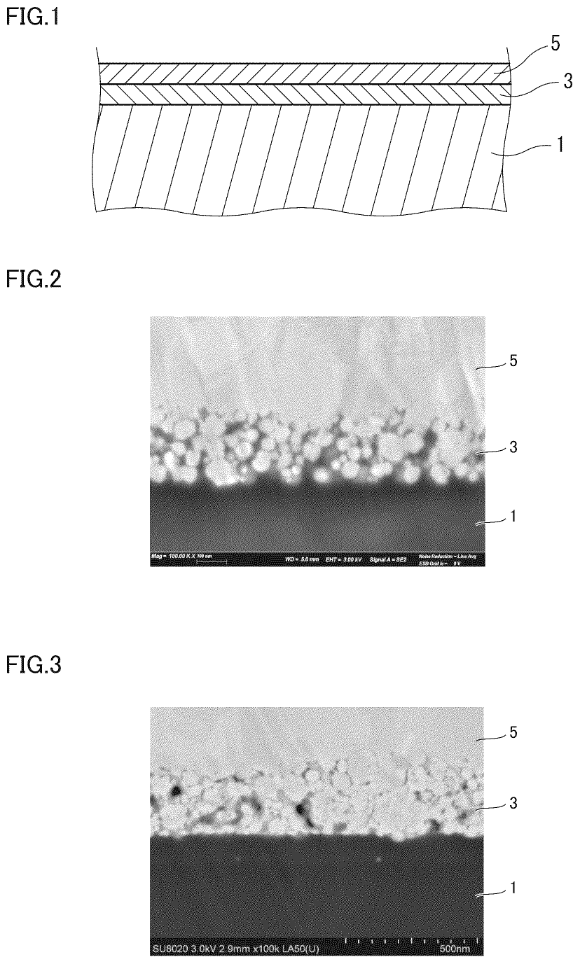

As shown in FIG. 1, a substrate for a printed wiring board according to the present embodiment includes: a base material layer 1 containing a thermoplastic resin as a main component; a metal nanoparticle layer 3; and a plating layer 5. Base material layer 1, metal nanoparticle layer 3, and plating layer 5 are stacked in this order. Some of metal nanoparticles in metal nanoparticle layer 3 are embedded in base material layer 1.

In other words, a surface portion of metal nanoparticle layer 3 on the base material layer side is embedded in base material layer 1. From a different point of view, the substrate for a printed wiring board has an irregularity structure at the boundary between metal nanoparticle layer 3 and base material layer 1. The irregularity structure is formed by the metal nanoparticles forming metal nanoparticle layer 3 and base material layer 1.

### (Base Material Layer)

Base material layer 1 contains a thermoplastic resin as a main component. The lower limit of the content of the thermoplastic resin in base material layer 1 is 50% by mass, preferably 80% by mass, more preferably 90% by mass or more, further more preferably 95% by mass or more, and may be 100% by mass. Base material layer 1 may contain additives such as an antistatic agent and a filler in addition to the thermoplastic resin.

The glass transition temperature of the thermoplastic resin may be 50° C. or higher and 400° C. or lower, may be 100° C. or higher and 350° C. or lower, may be 150° C. or higher and 300° C. or lower, or may be 150° C. or higher and 250° C. or lower. When the thermoplastic resin has a glass transition temperature in the above-mentioned range, the metal nanoparticle layer is easily embedded in the base material layer in a heat treatment step described later, so that the adhesiveness between the base material layer and the metal nanoparticle layer is further improved. In this case, the “glass transition temperature” means an intermediate point glass transition temperature measured by a differential scanning calorimeter (DSC) according to JIS-K-7121:2012.

Examples of the thermoplastic resin include polyimide (PI), polyamideimide (PAI), polyether ether ketone (PEEK), polyethylene naphthalate (PEN), polytetrafluoroethylene (PTFE), polystyrene (PS), polyvinyl chloride (PVC), polymethyl methacrylate (PMMA), polyethylene terephthalate (PET), polyamide, acrylonitrile-butadiene-styrene copolymer (ABS), and the like. Among them, polyimide is preferable in terms of heat resistance.

The average thickness of base material layer 1 should only be set as appropriate depending on the intended use. For example, the lower limit of the average thickness of base material layer 1 is preferably 1.5 μm, and more preferably 2.5 μm. Also, the upper limit of the average thickness of base material layer 1 is preferably 2.0 mm, and more preferably 1.6 mm. When the average thickness of base material layer 1 is below the lower limit, the strength of the substrate for a printed wiring board may become insufficient. On the other hand, when the average thickness of base material layer 1 exceeds the upper limit, sufficient reduction in thickness may become difficult. The “average thickness of the base material layer” means the average value of the distances in the thickness direction at arbitrary ten points between the outermost surface of base material layer 1 on the side opposite to metal nanoparticle layer 3 and the outermost surface of base material layer 1 that is in contact with metal nanoparticle layer 3.

Base material layer 1 may be a rigid layer or a flexible layer.

### (Metal Nanoparticle Layer)

Metal nanoparticle layer 3 is stacked directly on base material layer 1 (i.e., without another layer such as an adhesive layer interposed therebetween), and some of the metal nanoparticles in metal nanoparticle layer 3 are embedded in base material layer 1. Metal nanoparticle layer 3 is a layer containing metal nanoparticles as a main component. The metal nanoparticle layer is preferably a sintered material of metal nanoparticles. When metal nanoparticle layer 3 is a sintered material of metal nanoparticles, the adhesiveness between base material layer 1 and metal nanoparticle layer 3 is further improved.

The lower limit of the average particle diameter of the metal nanoparticles is preferably 1 nm, more preferably 10 nm, and still more preferably 30 nm. On the other hand, the upper limit of the average particle diameter of the metal nanoparticles is preferably 500 nm, more preferably 300 nm, and still more preferably 100 nm. In the case where the average particle diameter of the metal nanoparticles is below the lower limit, when metal nano-ink is coated on base material layer 1 to form metal nanoparticle layer 3 as will be described later, the dispersibility and the dispersion stability of the metal nanoparticles in the metal nano-ink may decrease, which may lead to an uneven thickness of metal nanoparticle layer 3. On the other hand, when the average particle diameter of the metal nanoparticles exceeds the upper limit, the irregularities on the surface of metal nanoparticle layer 3 become significant, and thus, a fine conductive pattern may not be easily formed.

By sintering a plurality of metal nanoparticles, metal nanoparticle layer 3 is stacked on one or both of the surfaces of base material layer 1. Examples of the metal as a constituent of the metal nanoparticles include copper, nickel, aluminum, gold, silver, and the like. Among them, copper is preferable since it is excellent in conductivity and etching characteristics. In other words, the metal nanoparticles are preferably copper nanoparticles. When the metal nanoparticles are copper nanoparticles, metal nanoparticle layer 3 excellent in conductivity is easily formed, which is advantageous in forming a fine circuit.

Some of the metal nanoparticles in metal nanoparticle layer 3 are embedded in base material layer 1 as shown in FIG. 2, which will be described later. Some of the metal nanoparticles in metal nanoparticle layer 3 are embedded in base material layer 1, thus allowing for excellent adhesiveness between base material layer 1 and metal nanoparticle layer 3. On the other hand, the surface of metal nanoparticle layer 3 on the side opposite to base material layer 1 is smoother than the surface of the thermocompression-bonded metal foil, which results in a smooth outer surface of plating layer 5 on metal nanoparticle layer 3, so that a fine conductive pattern can be formed.

The lower limit of the average thickness of metal nanoparticle layer 3 is preferably 10 nm, more preferably 50 nm, and still more preferably 100 nm. On the other hand, the upper limit of the average thickness of metal nanoparticle layer 3 is preferably 1000 nm, more preferably 700 nm, and still more preferably 500 nm. When the average thickness of metal nanoparticle layer 3 is below the lower limit, cracks or the like may occur in metal nanoparticle layer 3, so that the conductivity may decrease. On the other hand, when metal nanoparticle layer 3 having an average thickness exceeding the upper limit is applied in formation of conductive patterns, it may become difficult to remove metal nanoparticle layer 3 between the conductive patterns. Note that the “average thickness of the metal nanoparticle layer” means an average value of the distances in the thickness direction at arbitrary ten points between the outermost surface of metal nanoparticle layer 3 that is in contact with base material layer 1 and the outermost surface of metal nanoparticle layer 3 on the side opposite to base material layer 1 (in this case, the surface being in contact with plating layer 5).

The lower limit of the 180-degree peel strength with which metal nanoparticle layer 3 is peeled off from base material layer 1 is preferably 5 N/cm, more preferably 7 N/cm, and still more preferably 10 N/cm. When the 180-degree peel strength is below the lower limit, the conductive pattern formed on the substrate for a printed wiring board may be easily peeled off from the substrate.

It is preferable that the surface of the base material layer from which the metal nanoparticle layer has been peeled off has marks of embedment including a plurality of recesses. When the surface of the base material layer from which the metal nanoparticle layer has been peeled off has marks of embedment including a plurality of recesses, some of the metal nanoparticles in the metal nanoparticle layer are sufficiently embedded in the surface of the base material layer, so that the adhesiveness between the base material layer and the metal nanoparticle layer can be improved.

In a plan view of the region of the surface of the base material layer from which the metal nanoparticle layer has been peeled off, the lower limit of the area ratio of the recesses is preferably 5%, more preferably 10%, and still more preferably 25%. When the area ratio of the recesses is within the above-mentioned range in a plan view of the region of the surface of the base material layer from which the metal nanoparticle layer has been peeled off, some of the metal nanoparticles in the metal nanoparticle layer are sufficiently embedded in the surface of the base material layer, thus allowing for excellent adhesiveness between the base material layer and the metal nanoparticle layer. Also, in a plan view of the region of the surface of the base material layer from which the metal nanoparticle layer has been peeled off, the upper limit of the area ratio of the recesses is preferably 90% from the viewpoint of the strength of the surface of the base material layer.

The lower limit of the maximum width among the widths of the recesses in the surface of the base material layer from which the metal nanoparticle layer has been peeled off is preferably 1 nm and more preferably 10 nm in a plan view. When the maximum width among the widths of the recesses in the surface of the base material layer from which the metal nanoparticle layer has been peeled off is 1 nm or more in a plan view, some of the metal nanoparticles in the metal nanoparticle layer are sufficiently embedded in the surface of the base material layer, so that the adhesiveness between the base material layer and the metal nanoparticle layer can be improved.

### (Plating Layer)

As the plating layer, an electroless plating layer, an electroplating layer, or the like is used. Plating layer 5 is directly stacked on the surface of metal nanoparticle layer 3 on the side opposite to base material layer 1. Plating layer 5 is formed by plating with plating metal. The plating metal fills voids in the sintered material constituting metal nanoparticle layer 3 and is stacked on the outer surface of the sintered material. The plating metal preferably fills all of the voids in the sintered material. In the substrate for a printed wiring board 1, the voids in the sintered material are filled with plating metal, thus preventing metal nanoparticle layer 3 from being peeled off from base material layer 1 from the portions of these voids in the sintered material as the points of origin of breakage.

As the metal forming plating layer 5, copper, nickel, cobalt, gold, silver, tin, alloys thereof, and the like are used. Among them, copper is preferable since it is relatively inexpensive and is excellent in etching characteristics. Specifically, plating layer 5 is preferably a copper plating layer.

The lower limit of the average thickness of plating layer 5 is preferably 50 nm, more preferably 100 nm, and still more preferably 200 nm. The upper limit of the average thickness of plating layer 5 is preferably 2.0 μm, more preferably 1.5 μm, and still more preferably 1.0 μm. When the average thickness of plating layer 5 is below the lower limit, it may be difficult to sufficiently fill the voids in the sintered material with the plating metal. On the other hand, when the average thickness of plating layer 5 exceeds the upper limit, plating requires more time, with the result that the productivity may decrease. Note that the “average thickness of the plating layer” means an average value of the distances in the thickness direction at arbitrary ten points between the outermost surface of plating layer 5 that is in contact with metal nanoparticle layer 3 and the outermost surface (the outer surface in this case) of plating layer 5 on the side opposite to metal nanoparticle layer 3.

### [Method of Manufacturing Substrate for Printed Wiring Board]

A method of manufacturing the substrate for a printed wiring board includes, for example, a step of stacking a metal nanoparticle layer on a surface of a base material layer containing a thermoplastic resin as a main component. The step of stacking includes steps of: coating a surface of the base material layer with metal nano-ink; and heat-treating a coating film of the metal nano-ink coated on the surface of the base material layer. Further, the step of stacking may be followed by a plating layer stacking step of stacking plating layer 5 on the outer surface of the metal nanoparticle layer (the surface on the side opposite to base material layer 1).

### (Step of Stacking Metal Nanoparticle Layer)

In the present step, a metal nanoparticle layer is stacked on the surface of the base material layer containing a thermoplastic resin as a main component. The present step includes steps of: coating the surface of the base material layer with metal nano-ink; and heat-treating a coating film of the metal nano-ink coated on the surface of the base material layer.

### [Metal Nano-Ink Coating Step]

In the above-mentioned step of forming a coating film, metal nano-ink containing metal nanoparticles is coated on the surface of base material layer 1 and then dried to form a coating film. The coating film may contain a dispersion medium and the like of the metal nano-ink.

### <Metal Nanoparticles>

The metal nanoparticles to be dispersed in the metal nano-ink can be manufactured by a high temperature treatment method, a liquid-phase reduction method, a gas-phase method, or the like. According to the liquid-phase reduction method among these methods, the manufacturing cost is further reduced, and additionally, the particle diameters of the metal nanoparticles can be easily made uniform by stirring or the like in an aqueous solution. By manufacturing the metal nanoparticles by a high temperature treatment method, a liquid-phase reduction method, a gas-phase method, or the like, for example, the average particle diameter of the metal nanoparticles is adjusted to be 1 nm or more and 500 nm or less.

In order to manufacture metal nanoparticles by a liquid-phase reduction method, for example, a water-soluble metal compound that is an origin of metal ions (a metal ion source) as a constituent of the metal nanoparticles and a dispersant may be dissolved in water, to which a reducing agent may be added to thereby cause a reduction reaction of the metal ions for a certain period of time. In the case of the liquid-phase reduction method, the shapes of the produced metal nanoparticles are equally spherical or granular, and also, the metal nanoparticles are formed as fine particles. Examples of the water-soluble metal compound as a metal ion source include copper (II) nitrate (Cu(NO₃)₂), copper (II) sulfate pentahydrate (CuSO₄·5H₂O), and the like as a copper ion source. Examples of the silver ion source include silver (I) nitrate (AgNO₃), silver methanesulfonate (CH₃SO₃Ag), and the like. Examples of the gold ion source include hydrogen tetrachloroaurate (III) tetrahydrate (HAuCl₄·4H₂O). Examples of the nickel ion source include nickel (II) chloride hexahydrate (NiCl₂·6H₂O), nickel (II) nitrate hexahydrate (Ni(NO₃)₂·6H₂O), and the like. Examples of the metal ion source other than the above include water-soluble compounds such as chloride, a nitric acid compound, and a sulfuric acid compound of metals other than the above.

As the reducing agent, various reducing agents each capable of reducing and depositing metal ions in a reaction system of a liquid phase (an aqueous solution) can be used. Examples of the reducing agent include sodium borohydride, sodium hypophosphite, hydrazine, ions of transition metals such as trivalent titanium ions and divalent cobalt ions, ascorbic acid, reducing sugars such as glucose and fructose, polyhydric alcohols such as ethylene glycol and glycerin, and the like. Among them, trivalent titanium ions are preferable as the reducing agent. The liquid-phase reduction method using trivalent titanium ions as a reducing agent is referred to as a titanium redox method. According to the titanium redox method, metal ions are reduced by an oxidation-reduction effect occurring when trivalent titanium ions are oxidized to tetravalent ions, and thus, metal nanoparticles are deposited. Since the metal nanoparticles obtained by the titanium redox method have small and uniform particle diameters, these metal nanoparticles are packed with higher density, and the coating film is formed more densely.

In order to adjust the particle diameters of the metal nanoparticles, the types and the blending ratio of the metal compound, the dispersant and the reducing agent should only be adjusted, and also, the stirring speed, the temperature, the time, pH, and the like should only be adjusted when the metal compound is subjected to a reduction reaction. The lower limit and the upper limit of the pH in the reaction system are preferably 7 and 13, respectively. The pH in the reaction system falling within this range makes it possible to obtain metal nanoparticles each having a minute particle diameter. With the use of a pH adjuster at this time, the pH in the reaction system can be easily adjusted to fall within the above-mentioned range. As a pH adjuster, common acids or alkalis such as hydrochloric acid, sulfuric acid, nitric acid, sodium hydroxide, sodium carbonate, and ammonia can be used. In particular, it is preferable to use nitric acid and ammonia that do not contain impurities such as an alkali metal, an alkaline earth metal, a halogen element, sulfur, phosphorus, and boron from the viewpoint of preventing deterioration of peripheral members.

As described above, the lower limit of the average particle diameter of the metal nanoparticles is preferably 1 nm, more preferably 10 nm, and still more preferably 30 nm. As described above, the upper limit of the average particle diameter of the metal nanoparticles is preferably 500 nm, more preferably 300 nm, and still more preferably 100 nm. When the average particle diameter of the metal nanoparticles is below the lower limit, the dispersibility and the stability of the metal nanoparticles in the metal nano-ink may decrease. On the other hand, when the average particle diameter of the metal nanoparticles exceeds the upper limit, the metal nanoparticles may tend to settle, and the density of the metal nanoparticles in the metal nano-ink coated on base material layer 1 may become uneven.

The lower limit of the content of the metal nanoparticles in the metal nano-ink is preferably 5% by mass, more preferably 10% by mass, and still more preferably 20% by mass. The upper limit of the content of the metal nanoparticles in the metal nano-ink is preferably 50% by mass, more preferably 40% by mass, and still more preferably 30% by mass. When the content of the metal nanoparticles is below the lower limit, the coating film may not be sufficiently dense. On the other hand, when the content of the metal nanoparticles exceeds the upper limit, the coating film may have an uneven thickness.

### <Other Components>

The metal nano-ink may contain a dispersant in addition to the metal nanoparticles. The dispersant is not particularly limited, and various types of dispersants capable of satisfactorily dispersing the metal nanoparticles are used.

The dispersant preferably does not contain sulfur, phosphorus, boron, halogen, and alkali from the viewpoint of preventing deterioration of peripheral members. Examples of a preferable dispersant include: a nitrogen-containing polymer dispersant such as polyethyleneimine and polyvinylpyrrolidone; a hydrocarbon-based polymer dispersant having a carboxy group in a molecule, such as polyacrylic acid and carboxymethyl cellulose; a polymer dispersant having a polar group, such as Poval (polyvinyl alcohol), a styrene-maleic acid copolymer, an olefin-maleic acid copolymer, and a copolymer having a polyethyleneimine moiety and a polyethylene oxide moiety in each molecule; and the like.

The lower limit and the upper limit of the molecular weight of the dispersant are preferably 2000 and 30000, respectively. With the use of the dispersant having a molecular weight falling within this range, the metal nanoparticles can be well dispersed in the metal nano-ink, and the coating film can be formed densely and without defects. When the molecular weight of the dispersant is below the lower limit, the effect of preventing aggregation of the metal nanoparticles in the metal nano-ink to maintain dispersion may not be sufficiently achieved. On the other hand, when the molecular weight of the dispersant exceeds the upper limit, the bulk of the dispersant becomes too large. Thus, at the time of heat treatment of the coating film, sintering of the metal nanoparticles with each other may be inhibited, so that voids may be formed. Further, if the bulk of the dispersant is too large, the coating film may become less dense, and decomposition residues of the dispersant may be produced, so that the conductivity may decrease.

The dispersant in the form of a solution dissolved in water or a water-soluble organic solvent may be blended in the metal nano-ink. When a dispersant is blended in the metal nano-ink, the lower limit of the content ratio of the dispersant is preferably 1 part by mass with respect to 100 parts by mass of the metal nanoparticles. On the other hand, the upper limit of the content ratio of the dispersant is preferably 60 parts by mass with respect to 100 parts by mass of the metal nanoparticles. When the content ratio of the dispersant is below the lower limit, the effect of preventing aggregation of the metal nanoparticles may become insufficient. On the other hand, when the content ratio of the dispersant exceeds the upper limit, at the time of the heat treatment of the coating film, the excessive dispersant may inhibit sintering of the metal nanoparticles to thereby produce voids, and also, the decomposition residues of the dispersant may remain as impurities in the metal nanoparticle layer to thereby decrease the conductivity.

As the dispersion medium in the metal nano-ink, for example, water is used. When water is used as a dispersion medium, the lower limit of the content ratio of water is preferably 20 parts by mass with respect to 100 parts by mass of the metal nanoparticles. The upper limit of the content ratio of water is preferably 1900 parts by mass with respect to 100 parts by mass of the metal nanoparticles. Water used as a dispersion medium serves, for example, to sufficiently swell the dispersant to cause the metal particles surrounded by the dispersant to be satisfactorily dispersed in the metal nano-ink. However, when the content ratio of water is below the lower limit, the effect of swelling the dispersant may become insufficient. On the other hand, when the content ratio of water exceeds the upper limit, the content ratio of the metal nanoparticles in the metal nano-ink becomes small, which may prevent formation of a satisfactory metal nanoparticle layer having a required thickness and density.

Various types of water-soluble organic solvents are used as an organic solvent to be blended as required in the metal nano-ink. Examples of such an organic solvent include: alcohols such as methyl alcohol, ethyl alcohol, n-propyl alcohol, isopropyl alcohol, n-butyl alcohol, isobutyl alcohol, sec-butyl alcohol, and tert-butyl alcohol; ketones such as acetone and methyl ethyl ketone; polyhydric alcohols such as ethylene glycol and glycerin, and other esters; glycol ethers such as ethylene glycol monoethyl ether, diethylene glycol monobutyl ether; and the like.

The content ratio of the organic solvent is preferably 30 parts by mass or more and 900 parts by mass or less with respect to 100 parts by mass of the metal nanoparticles. When the content ratio of the organic solvent is below the lower limit, the effect of adjusting the viscosity and the vapor pressure of the metal nano-ink by the organic solvent may not be sufficiently achieved. On the other hand, when the content ratio of the organic solvent exceeds the upper limit, the effect of swelling the dispersant by water becomes insufficient, which may cause aggregation of the metal nanoparticles in the metal nano-ink.

When the metal nanoparticles are manufactured by the liquid-phase reduction method, the metal nanoparticles deposited in the reaction system of the liquid phase (aqueous solution) may be once powdered through processes such as filtration, washing, drying, and disintegration, and then may be contained in the metal nano-ink. In this case, the metal nano-ink containing the metal nanoparticles can be prepared by mixing powdery metal nanoparticles, a dispersion medium such as water together with a dispersant, an organic solvent and the like as required, at a prescribed ratio. At this time, it is preferable to prepare metal nano-ink using, as a starting material, a liquid phase (an aqueous solution) obtained by depositing metal nanoparticles. Specifically, the liquid phase (an aqueous solution) containing the deposited metal nanoparticles is subjected to treatments such as ultrafiltration, centrifugation, water washing, and electrodialysis to thereby remove impurities. Then, the concentration of the metal nanoparticles is adjusted as required by concentrating the metal nanoparticles to remove water or by adding water to the metal nanoparticles for dilution. Then, an organic solvent is blended at a prescribed ratio as required, to thereby prepare metal nano-ink containing the metal nanoparticles. According to the present method, at the time of drying of the metal nanoparticles, generation of coarse and irregular particles resulting from aggregation can be prevented, so that a dense and uniform metal nanoparticle layer is easily formed.

<Method of Coating with Metal Nano-Ink>

As a method of coating the surface of base material layer 1 with the metal nano-ink having metal nanoparticles dispersed therein, conventionally known coating methods can be used, including a spin coating method, a spray coating method, a bar coating method, a die coating method, a slit coating method, a roll coating method, a dip coating method, and the like. Further, the metal nano-ink may be coated on only a part of the surface of base material layer 1 by screen printing, a dispenser, or the like. After coating with the metal nano-ink, a coating film is formed, for example, by drying at a temperature of room temperature or higher. The upper limit of the drying temperature is preferably 100° C., and more preferably 40° C. When the drying temperature exceeds the upper limit, rapid drying of the coating film may cause cracks or the like in the coating film.

### (Step of Heat-Treating Coating Film)

In the present step, the coating film of the metal nano-ink coated on the surface of the base material layer is heat-treated. By heat-treating the coating film formed on the base material layer, the metal nanoparticle layer is stacked on the surface of the base material layer.

### <Heat Treatment>

The metal nanoparticles are sintered with each other by the heat treatment, and some of the metal nanoparticles in the metal nanoparticle layer are embedded in the base material layer, and also, the metal nanoparticle layer is adhered to the base material layer. The dispersant and other organic substances that may be contained in the metal nano-ink are volatilized or decomposed by the heat treatment.

The above-mentioned heat treatment is performed at a temperature equal to or higher than the glass transition temperature (° C.) of the thermoplastic resin that is a main component of the base material layer. The lower limit of the heat treatment temperature is the glass transition temperature of the thermoplastic resin, and is preferably +10° C. of the glass transition temperature of the thermoplastic resin, more preferably +20° C. of the glass transition temperature, and still more preferably +30° C. of the glass transition temperature. By setting the lower limit of the heat treatment temperature to fall within the above-mentioned range, the surface portion of the base material layer is easily softened, so that the metal nanoparticle layer can be easily embedded in the base material layer, and thus, the adhesiveness between the base material layer and the metal nanoparticle layer can be sufficiently improved. The upper limit of the heat treatment temperature is not particularly limited as long as it falls within a temperature range in which the base material layer does not undergo deformation or thermal decomposition.

### (Step of Stacking Plating Layer)

Examples of the metal used for plating in the step of stacking a plating layer include copper, nickel, cobalt, gold, silver, tin, and the like, among which copper is preferable. The above-mentioned plating procedure is not particularly limited, and plating may be performed by well-known means, for example, together with the treatments such as a cleaner step, a water washing step, an acid treatment step, a water washing step, a pre-dip step, an activator step, a water washing step, a reduction step, and a water washing step.

In these steps, after plating layer 5 is formed on metal nanoparticle layer 3, a heat treatment may be further performed. By performing a heat treatment after plating layer 5 is formed, the adhesiveness between base material layer 1 and metal nanoparticle layer 3 can be further improved. The temperature of the heat treatment after plating can be the same as the temperature of the heat treatment in the above-mentioned heat treatment step.

According to the method of manufacturing a substrate for a printed wiring board, the temperature of the above-mentioned heat treatment is equal to or higher than the glass transition temperature of the thermoplastic resin, and thereby, the surface portion of the base material layer is easily softened, so that the metal nanoparticle layer can be easily embedded in the base material layer. This makes it possible to manufacture a substrate for a printed wiring board, the substrate being excellent in adhesiveness between the base material layer and the metal nanoparticle layer.

### (Application of Substrate for Printed Wiring Board to Printed Wiring Board)

The substrate for a printed wiring board can be used for manufacturing a printed wiring board by a subtractive method or a semi-additive method. In other words, a printed wiring board manufactured using the substrate for a printed wiring board has a conductive pattern including a layer obtained by patterning a metal nanoparticle layer. This substrate for a printed wiring board is suitable for a printed wiring board manufactured using a semi-additive method.

In the subtractive method, a photosensitive resist is formed to cover the surface of the plating layer of the substrate for a printed wiring board. Then, through exposure, development, and the like, this resist is subjected to patterning corresponding to a conductive pattern. Then, using the patterned resist as a mask, the plating layer and the metal nanoparticle layer in portions other than the conductive pattern are removed by etching. Finally, the remaining resist is removed to thereby obtain a printed wiring board having a conductive pattern formed from the remaining portions of the plating layer and the metal nanoparticle layer in the substrate for a printed wiring board.

In the semi-additive method, for example, a photosensitive resist is formed to cover the surface of the plating layer of the substrate for a printed wiring board. Then, through exposure, development, and the like, this resist is subjected to patterning to provide an opening corresponding to a conductive pattern. Subsequently, plating is performed using the patterned resist as a mask to thereby selectively stack a conductor layer using the plating layer as a seed layer exposed at the opening of the mask. Then, after the resist is peeled off, etching is performed to remove the surface of the conductor layer and also remove the plating layer and the metal nanoparticle layer each having no conductor layer formed thereon, thus fabricating a printed wiring board having a conductive pattern. The semi-additive method makes it possible to form a fine conductive pattern having wires, for example, having an average line width of 10 μm or more and 40 μm or less, and an average pitch of 20 μm or more and 50 μm or less.

### <Advantages>

The substrate for a printed wiring board is excellent in adhesiveness and allows a fine conductive pattern to be formed thereon.

### OTHER EMBODIMENTS

It should be understood that the embodiments disclosed herein are illustrative and non-restrictive in every respect. The scope of the present invention is not limited to the configurations of the above-described embodiments but defined by the scope of the claims, and is intended to include any modifications within the meaning and scope equivalent to the scope of the claims.

The above-described embodiments have been described with regard to the configuration in which the substrate for a printed wired board includes only a base material layer containing a thermoplastic resin as a main component. However, the substrate for a printed wiring board may further include a base material layer (a second base material layer) containing a thermosetting resin as a main component on the side opposite to the metal nanoparticle layer in the base material layer (a first base material layer) containing the above-mentioned thermoplastic resin as a main component. By further providing the base material layer containing the above-mentioned thermosetting resin as a main component, the dimensional stability of the base material layer can be improved. In the substrate for a printed wiring board, one or a plurality of first base material layers and one or a plurality of second base material layers may be stacked. In this case, a first base material layer should only be stacked on the outermost side of the one or the plurality of first base material layers, and a metal nanoparticle layer should only be stacked on the surface of this stacked first base material layer.

Specifically, for example, it is preferable that the base material layer includes a first resin layer containing a thermoplastic resin as a main component and a second resin layer containing a thermosetting resin as a main component, and the second resin layer, the first resin layer, and the metal nanoparticle layer are stacked in this order. Further, it is preferable that the base material layer includes a first resin layer containing a first thermoplastic resin as a main component, a second resin layer containing a thermosetting resin as a main component, and a third resin layer containing a second thermoplastic resin as a main component, the third resin layer, the second resin layer, and the first resin layer are stacked in this order, and the metal nanoparticle layer is stacked at least on a surface of the first resin layer or the third resin layer. The first thermoplastic resin and the second thermoplastic resin may be the same material or different materials. When the base material layer includes the first resin layer containing a thermoplastic resin as a main component, the second resin layer containing a thermosetting resin as a main component, and the third resin layer containing a thermoplastic resin as a main component, the dimensional stability of the base material layer can be further improved.

### EXAMPLES

Hereinafter, the present invention will be described more specifically with reference to examples, but the present invention is not limited to the following examples.

### Examples 1 to 3 and Comparative Example 1

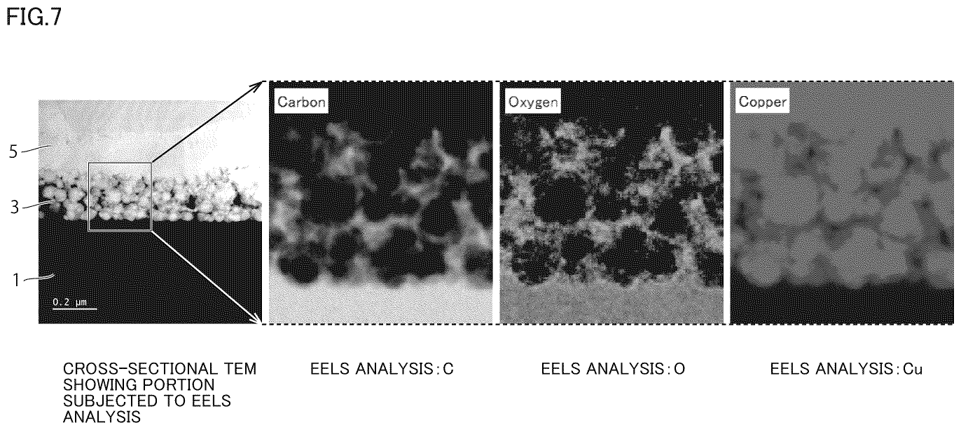

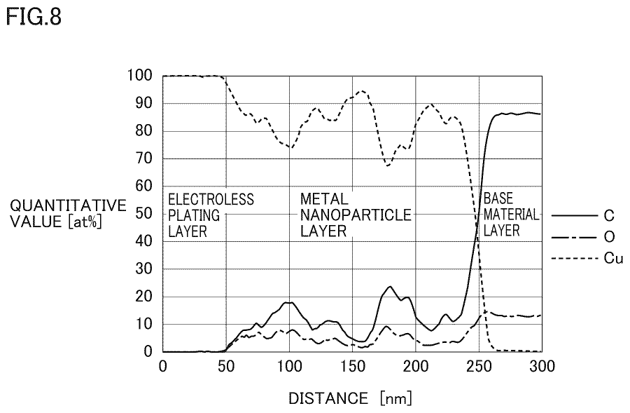

In this case, UPILEX-VT (registered trademark) having an average thickness of 25 μm and manufactured by Ube Industries Co., Ltd. was used in which, as a base material layer, a first base material layer containing thermoplastic polyimide having a glass transition temperature of 240° C. as a main component was provided on both sides of a second base material layer containing thermosetting polyimide as a main component. As metal nano-ink, metal nano-ink containing copper nanoparticles having an average particle size of 80 nm was used. This metal nano-ink was coated on both surfaces of the base material layer, dried at room temperature, and then heat-treated at a heat treatment temperature shown in Table 1 for 120 minutes under a nitrogen atmosphere to thereby form a metal nanoparticle layer having an average thickness of 150 nm. Then, electroless copper plating was conducted on the metal nanoparticle layer to form a plating layer having an average thickness of 150 nm. FIG. 2 shows a photograph (at a magnification of 100000×) taken with an electron microscope and showing a cross section of a substrate for a printed wiring board of Example 1. FIGS. 7 and 8 each show the results obtained by an EELS analysis through an observation of the cross section with a transmission electron microscope. FIG. 7 shows a cross-sectional TEM view on the leftmost side, in which base material layer 1, metal nanoparticle layer 3, and plating layer 5 are arranged in this order from the bottom. In this cross-sectional TEM view, the analyzed portion is shown within a rectangular frame and includes base material layer 1, metal nanoparticle layer 3, and plating layer 5. Further, the results of the EELS analysis about carbon, oxygen, and copper are sequentially shown on the right side of the cross-sectional TEM view on the leftmost side. Carbon is an element mainly forming the base material, and oxygen is an element also contained in the base material. Copper is an element forming metal nanoparticles. These figures also show that an irregularity structure exists at the boundary between metal nanoparticle layer 3 and base material layer 1. Further, FIG. 8 shows a graph of carbon (C), oxygen (O), and copper (Cu) obtained by line extraction from the results of the EELS analysis. In the graph, the horizontal axis represents a distance and the vertical axis represents a quantitative value that is obtained by integrating the breadth of 200 nm in units of atom c %. In FIG. 8, the quantitative value of copper sharply decreases in a region from about 235 nm to about 260 nm. In contrast, the quantitative value of carbon sharply increases in a region from about 235 nm to about 260 nm. It is construed that the region from about 235 nm to about 260 nm where the quantitative value of copper sharply decreases is a boundary between the metal nanoparticle layer and the base material layer and corresponds to an irregularity structure portion. Further, the portion of embedment and the surface portion of the metal nanoparticle layer on the base material layer side that are described in the present application are herein construed as ranging from about 235 nm to about 260 nm. Further, the outermost surface of the metal nanoparticle layer on the base material layer side is herein construed as a region of about 260 nm. Further, in the region from about 50 nm to about 235 nm, the main component in units of atom c % is copper, but carbon and oxygen forming the base material layer are also slightly contained. The region from about 50 nm to about 235 nm corresponds to the metal nanoparticle layer containing copper as a main component, but can also be construed as a region of a mixture also slightly containing elements forming the base material layer.

### Example 4

As the base material layer, EXPEEK (registered trademark) having an average thickness of 25 μm and manufactured by Kurabo Industries Ltd. was used in which polyetheretherketone having a glass transition temperature of 165° C. was contained as a main component. As metal nano-ink, metal nano-ink containing copper nanoparticles having an average particle size of 80 nm was used. This metal nano-ink was coated on both surfaces of the base material layer, dried at room temperature, and then heat-treated at a heat treatment temperature shown in Table 1 for 120 minutes under a nitrogen atmosphere to thereby form a metal nanoparticle layer having an average thickness of 150 nm. Then, electroless copper plating was conducted on the metal nanoparticle layer to thereby form a plating layer having an average thickness of 150 nm.

### Comparative Example 2

A substrate for a printed board of Comparative Example 2 was fabricated in the same manner as in Example 1 except for using APICAL NPI manufactured by KANEKA CORPORATION, having an average thickness of 25 μm and containing thermosetting polyimide as a main component. FIG. 3 shows a photograph (at a magnification of 100000×) taken in the same manner as in Example 1 and showing a cross section of the substrate for a printed wiring board of Comparative Example 2.

### [Evaluation]

### (180-Degree Peel Strength Test)

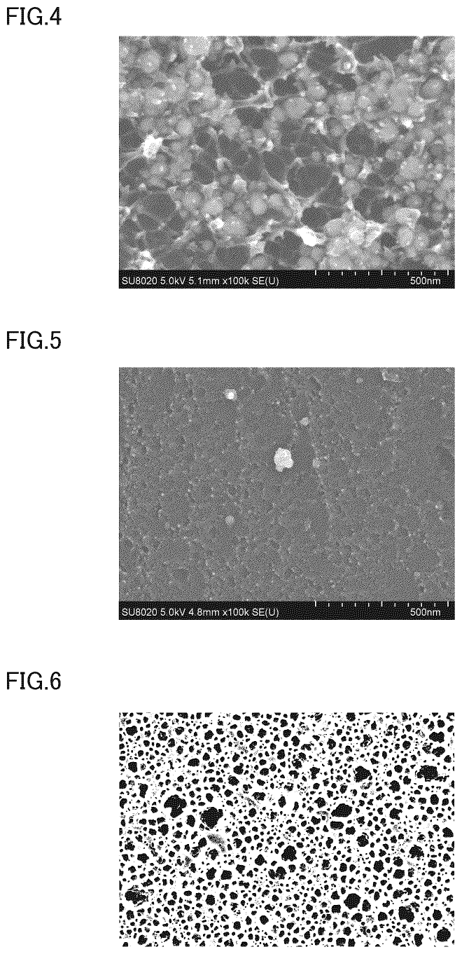

The obtained substrate for a printed board of Example 1 was subjected to a peeling test according to JIS-K6854-2:1999 “Adhesives—Determination of peel strength of bonded assemblies—Part 2:180 degree peel” to measure the 180-degree peel strength with which the metal nanoparticle layer having a plating layer stacked thereon was peeled off from the base material layer. The results are shown in Table 1. Further, FIG. 4 (Example 1) and FIG. 5 (Comparative Example 2) show photographs (at a magnification of 100000×) taken with an electron microscope and each showing the surface of the base material layer exposed after the peeling test in Example 1 and Comparative Example 2.

(Rate of Change in Arithmetic Mean Roughness Ra at Interface with Metal Nanoparticle Layer in Base Material Layer before and after Heat Treatment Step)

As to the interface with the metal nanoparticle layer in the base material layer before and after the heat treatment step, the metal nanoparticle layer having the plating layer stacked thereon was peeled off from the base material layer to thereby expose the surface of the base material layer, and from this exposed surface, the remaining metal nanoparticle layer was removed with the use of a copper (II) chloride aqueous solution.

Then, according to JIS-B0601 (2013), an arithmetic mean roughness Ra was measured using a scanning probe microscope (SPM) to calculate an average value of arithmetic mean roughnesses Ra obtained at five positions. Then, by the following equation, the rate of change in arithmetic mean roughness Ra at the interface with the metal nanoparticle layer in the base material layer before and after the heat treatment step was calculated.

$$Rate of change [ \% ] in arithmetic mean roughness Ra = ( arithmetic mean roughness Ra at interface with metal nanoparticle layer in base material layer after heat treatment step - arithmetic mean roughness Ra at interface with metal nanoparticle layer in base material layer before heat treatment step ) / ( arithmetic mean roughness Ra at interface with metal nanoparticle layer in base material layer heat treatment step ) \times 100$$

The “arithmetic mean roughness Ra” means an average value of arithmetic mean roughnesses Ra at arbitrary five positions according to JIS-B0601 (2013). Arithmetic mean roughness Ra at each of arbitrary five positions means a value obtained in the following way. Specifically, from a roughness curve, a portion of the roughness curve by a reference length (L) in the direction of an average line of the roughness curve from a position 0 to a position L is extracted at each of the five positions. The X axis is defined as the direction of the average line of this extracted portion, and the Y axis is defined as the direction of the longitudinal magnification. Then, assuming that the roughness curve is represented by y=f (x), the value determined by the following equation (1) and expressed in micrometer (μm) is referred to as the above-mentioned arithmetic mean roughness Ra at each of the arbitrary five positions.

$$\begin{matrix}[ Equation 1 ] & \\ {R}_{a} = \frac{1}{L} {\int }_{0}^{L} \vert f ( x ) \vert dx & ( 1 )\end{matrix}$$

(Observation of Marks of Embedment with Scanning Electron Microscope)

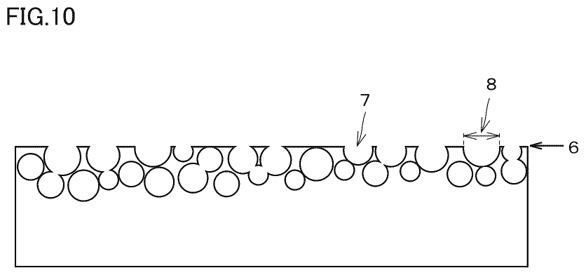

The exposed surface of the base material layer of Example 1, which was exposed by peeling off the metal nanoparticle layer in the above-mentioned peeling test, was observed with a scanning electron microscope to check for existence or non-existence of a mark of embedment (a recess). Further, the maximum width among widths of the recesses was measured. FIG. 10 shows a schematic cross-sectional view for illustrating a recess 7 as a mark of embedment and a recess maximum width 8 on a base material layer surface 6. The recess maximum width is obtained through an observation in one field of view at a magnification of 50000×.

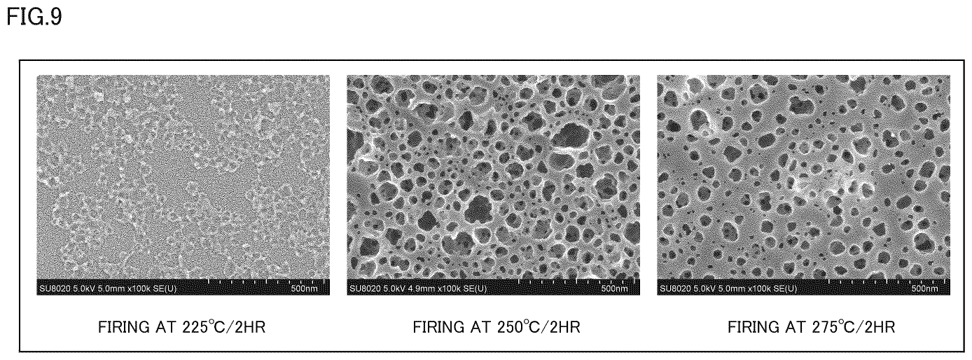

(Area Ratio of Recesses in Plan View of Region of Surface of Base Material Layer from which Metal Nanoparticle Layer Has been Peeled Off) The area ratio [%] of the recesses in a plan view of the region of the surface of the base material layer from which the metal nanoparticle layer has been peeled off was obtained in the following way. Specifically, the surface of the base material layer exposed after the peeling test was etched with copper chloride, the etched surface was photographed by an electron microscope, and recesses (black regions) were accumulated to calculate the area ratio [%]. FIG. 9 shows an image shown at a magnification of 100000× obtained by an observation of the interface of the base material etched with copper chloride before binarization. FIG. 9 shows Comparative Example 1 at 225° C., Example 2 at 250° C., and Example 1 at 275° C. FIG. 6 shows a binary image at a magnification of 50000× showing a region from which a metal nanoparticle layer has been peeled off in Example 1.

Table 1 shows the results of evaluation about: the 180-degree peel strength; the rate of change in arithmetic mean roughness Ra at the interface with the metal nanoparticle layer in the base material layer before and after the heat treatment step; the observation of the marks of embedment with a scanning electron microscope; the area ratio of the recesses in the region of the surface of the base material layer from which the metal nanoparticle layer has been peeled off; and the maximum width of the recesses. Note that “-” in Table 1 indicates that the measurement target was too small or the like and therefore not evaluated. Further, in this case, “Mark Exists” in Table 1 indicates that a recess having a width of 1 nm or more exists.

TABLE 1

| | | | | 180-Degree | Arithmetic | Rate of | | Area Ratio of | |
|---|---|---|---|---|---|---|---|---|---|
| | | | | Peel Strength | Mean | Change in | | Recesses in | |
| | | | | with which | Roughness | Arithmetic | | Region of | |
| | | | | Metal | Ra at | Mean | | Surface of | |
| | | Glass | | Nanoparticle | Interface in | Roughness Ra | | Base Material | |
| | | Transition | | Layer is | Base | at Interface in | Observation | Layer from | |
| | | Point of | | Peeled Off | Material | Base Material | of Mark of | which Metal | |
| | | Base | Heat | from Base | Layer after | Layer before | Embedment | Nanoparticle | |
| | Base | Material | Treatment | Material | Heat | and after Heat | by Scanning | Layer has been | Maximum |
| | Material | Resin | Temperature | Layer | Treatment | Treatment | Electron | Peeled off | Width of |
| | Layer | [° C.] | [° C.] | [N/cm] | [nm] | Step [%] | Microscope | [%] | Recesses |
| Example 1 | Thermoplastic | 240 | 275 | 16.5 | 14.2 | 246.4 | Mark Exists | 32.5 | 186 |
| | Polyimide | | | | | | | | |
| Example 2 | Thermoplastic | 240 | 250 | 16.0 | 10.5 | 157.0 | Mark Exists | 25.0 | 129 |
| | Polyimide | | | | | | | | |
| Example 3 | Thermoplastic | 240 | 240 | 7.8 | 7.6 | 85.4 | Mark Exists | 5.7 | 114 |
| | Polyimide | | | | | | | | |
| Example 4 | Polyether | 165 | 200 | 14.1 | — | — | Mark Exists | 32.2 | 144 |
| | Ether Ketone | | | | | | | | |
| Comparative | Thermoplastic | 240 | 225 | 3.3 | 4.8 | 16.9 | No Mark | — | — |
| Example 1 | Polyimide | | | | | | | | |
| Comparative | Thermosetting | — | 350 | 2.4 | 4.5 | 10.3 | No Mark | — | — |
| Example 2 | Polyimide | | | | | | | | |

As shown in Table 1, in Examples 1 to 4 in which the base material layer containing a thermoplastic resin as a main component is included and some of the metal nanoparticles in the metal nanoparticle layer are embedded in the base material layer, the 180-degree peel strength was significantly higher than those in Comparative Examples 1 and 2. Further, in Examples 1 to 4, the rate of change in arithmetic mean roughness Ra at the interface with the metal nanoparticle layer in the base material layer before and after the heat treatment step was significantly higher than those in Comparative Examples 1 and 2. The photograph of the cross section (in which base material layer 1, metal nanoparticle layer 3, and plating layer 5 are stacked in this order from the bottom) of Example 1 in FIG. 2 shows that the metal nanoparticle layer is embedded in the base material layer of Example 1 that contains a thermoplastic resin as a main component. Further, the peel strength was higher as the area ratio of the recesses was larger in a plan view of the region of the surface of the base material layer from which the metal nanoparticle layer has been peeled off. Further, as shown in the photograph of the surface from which the metal nanoparticle layer has been peeled off in Example 1 in FIG. 4, in Example 1, the metal nanoparticle layer partially remained on the base material layer after the peeling test. This also showed that the metal nanoparticle layer was firmly adhered to the base material layer in Example 1.

On the other hand, as shown in the photograph of the cross section (in which base material layer 1, metal nanoparticle layer 3, and plating layer 5 are stacked in this order from the bottom) of Comparative Example 2 in FIG. 3, no metal nanoparticle layer was embedded in the base material layer of Comparative Example 2 that contains a thermosetting resin as a main component. Further, as shown in the photograph of the surface from which the metal nanoparticle layer has been peeled off in Comparative Example 2 in FIG. 5, no metal nanoparticle layer remained in the base material layer after the peeling test. This also showed that the metal nanoparticle layer was not firmly adhered to the base material layer in Comparative Example 2.

### [Supplementary Notes]

The following configuration can be provided as a substrate for a printed wiring board, the substrate being excellent in adhesiveness and allowing a fine conductive pattern to be formed thereon.

### [Supplementary Note 1]

A substrate for a printed wiring board, the substrate comprising:
a base material layer containing a thermoplastic resin;
a metal nanoparticle layer stacked on one or both of surfaces of the base material layer; and
a plating layer stacked on a surface of the metal nanoparticle layer on a side opposite to the base material layer, wherein
a surface portion of the metal nanoparticle layer on a side close to the base material layer is embedded in the base material layer.

### [Supplementary Note 2]

The substrate for a printed wiring board according to [Supplementary Note 1], wherein a 180-degree peel strength of the metal nanoparticle layer with which the metal nanoparticle layer is peeled off from the base material layer is 5 N/cm or more.

### [Supplementary Note 3]

The substrate for a printed wiring board according to [Supplementary Note 1] or [Supplementary Note 2], wherein an average particle diameter of metal nanoparticles in the metal nanoparticle layer is 1 nm or more and 500 nm or less.

### [Supplementary Note 4]

The substrate for a printed wiring board according to [Supplementary Note 1], [Supplementary Note 2], or [Supplementary Note 3], wherein, after the metal nanoparticle layer is peeled off, a surface of the base material layer has a mark of embedment including a plurality of recesses.

### [Supplementary Note 5]

The substrate for a printed wiring board according to any one of [Supplementary Note 1] to [Supplementary Note 4], wherein, in a plan view of a region of the surface of the base material layer from which the metal nanoparticle layer has been peeled off, an area ratio of the recesses is 5% or more.

### [Supplementary Note 6]

The substrate for a printed wiring board according to any one of [Supplementary Note 1] to [Supplementary Note 5], wherein, at the surface of the base material layer from which the metal nanoparticle layer has been peeled off, a maximum width among widths of the recesses is 1 nm or more in a plan view.

### [Supplementary Note 7]

The substrate for a printed wiring board according to any one of [Supplementary Note 1] to [Supplementary Note 6], wherein the thermoplastic resin is polyimide.

### [Supplementary Note 8]

The substrate for a printed wiring board according to any one of [Supplementary Note 1] to [Supplementary Note 7], wherein
the base material layer includes a first resin layer containing a thermoplastic resin as a main component and a second resin layer containing a thermosetting resin as a main component, and
the second resin layer, the first resin layer, and the metal nanoparticle layer are stacked in this order.

### [Supplementary Note 9]

The substrate for a printed wiring board according to any one of [Supplementary Note 1] to [Supplementary Note 7], wherein
the base material layer includes a first resin layer containing a thermoplastic resin as a main component, a second resin layer containing a thermosetting resin as a main component, and a third resin layer containing a thermoplastic resin as a main component,
the third resin layer, the second resin layer, and the first resin layer are stacked in this order, and
the metal nanoparticle layer is stacked at least on a surface of the first resin layer or the third resin layer.

### REFERENCE SIGNS LIST

1 base material layer, 3 metal nanoparticle layer, 5 plating layer, 6 base material layer surface portion, 7 recess as mark of embedment, 8 recess maximum width.

1. A substrate for a printed wiring board, the substrate comprising:
a base material layer containing a thermoplastic resin;
a metal nanoparticle layer; and
a plating layer, wherein
the base material layer, the metal nanoparticle layer, and the plating layer are stacked in this order, and
some of metal nanoparticles in the metal nanoparticle layer are embedded in the base material layer.

2. The substrate for a printed wiring board according to claim 1, wherein a 180-degree peel strength of the metal nanoparticle layer with which the metal nanoparticle layer is peeled off from the base material layer is 5 N/cm or more.

3. The substrate for a printed wiring board according to claim 1, wherein an average particle diameter of the metal nanoparticles in the metal nanoparticle layer is 1 nm or more and 500 nm or less.

4. The substrate for a printed wiring board according to claim 1, wherein, after the metal nanoparticle layer is peeled off, a surface of the base material layer has a mark of embedment including a plurality of recesses.

5. The substrate for a printed wiring board according to claim 4, wherein, in a plan view of a region of the surface of the base material layer from which the metal nanoparticle layer has been peeled off, an area ratio of the recesses is 5% or more.

6. The substrate for a printed wiring board according to claim 4 or 5, wherein, at the surface of the base material layer from which the metal nanoparticle layer has been peeled off, a maximum width among widths of the recesses is 1 nm or more in a plan view.

7. The substrate for a printed wiring board according to claim 1, wherein the thermoplastic resin is polyimide.

8. The substrate for a printed wiring board according to claim 1, wherein
the base material layer includes a first resin layer containing the thermoplastic resin as a main component and a second resin layer containing a thermosetting resin as a main component, and
the second resin layer, the first resin layer, and the metal nanoparticle layer are stacked in this order.

9. The substrate for a printed wiring board according to claim 1, wherein
the thermoplastic resin includes a first thermoplastic resin and a second thermoplastic resin,
the base material layer includes a first resin layer containing the first thermoplastic resin as a main component, a second resin layer containing a thermosetting resin as a main component, and a third resin layer containing the second thermoplastic resin as a main component,
the third resin layer, the second resin layer, and the first resin layer are stacked in this order, and
the metal nanoparticle layer is stacked at least on a surface of the first resin layer or the third resin layer.
